(19) United States
(12) Patent Application Publication
(10) Pub. No.: US 2015/0155163 A1
(43) Pub. Date: Jun. 4, 2015

(54) SEMICONDUCTOR DEVICES AND METHODS OF MANUFACTURING THE SAME

(71) Applicant: Samsung Electronics Co., Ltd., Suwon-Si (KR)

(72) Inventors: Chang-Jin KIM, Hwaseong-si (KR); Young-Su CHO, Suwon-si (KR); Jung-Sik HA, Daegu (KR)

(21) Appl. No.: 14/492,401

(22) Filed: Sep. 22, 2014

(30) Foreign Application Priority Data
Dec. 3, 2013 (KR) 10-2013-0148916

(51) Int. Cl. H01L 21/02; H01L 29/78; H01L 27/108

(52) U.S. Cl. CPC H01L 21/02274; H01L 27/108; H01L 27/10847; H01L 29/7843; H01L 21/022

(57) ABSTRACT

A semiconductor device includes a structure including a transistor and a capacitor on a substrate, an upper insulation layer covering the structure, a first passivation layer and a second passivation layer. The first passivation layer is formed on the upper insulation layer to prevent or reduce a leakage charge from the capacitor. The second passivation layer is formed on the first passivation layer and has a compressive property.

### CROSS-REFERENCE TO RELATED APPLICATION

This application claims priority under 35 USC §119 to Korean Patent Application No. 10-2013-0148916, filed on Dec. 3, 2013 in the Korean Intellectual Property Office (KIPO), the contents of which are incorporated by reference herein in their entirety.

### BACKGROUND

1. Field

Example embodiments relate to semiconductor devices and methods of manufacturing the same. More particularly, example embodiments relate to semiconductor devices including a passivation layer and methods of manufacturing the same.

2. Description of the Related Art

In a formation of a semiconductor device, e.g., a dynamic random access memory (DRAM) device, structures including a transistor, a capacitor, a wiring, etc., may be formed on a substrate, e.g., a silicon wafer, and then a passivation layer may be formed on the substrate. The passivation layer may protect the structures from an external environment or an external shock.

However, if a thickness of the passivation layer is excessively increased, operational characteristics of the semiconductor devices may be deteriorated.

### SUMMARY

According to example embodiments, there is provided a semiconductor device. The semiconductor device includes a structure including a transistor and a capacitor on a substrate, an upper insulation layer covering the structure, a first passivation layer and a second passivation layer. The first passivation layer is formed on the upper insulation layer. The second passivation layer is formed on the first passivation layer and has a compressive property.

In example embodiments, the first passivation layer and the second passivation layer may include silicon nitride. A layer property of the first passivation layer may be different from that of the second passivation layer.

In example embodiments, the second passivation layer may have a layer density greater than that of the first passivation layer.

In example embodiments, the first passivation layer may have a hydrogen content greater than that of the second passivation layer.

In example embodiments, the first passivation layer may have a compressive force less than about 2.0×10⁹ dyne/cm², and the second passivation layer may have a compressive force ranging from about 6.0×10⁹ dyne/cm² to about 9.0×10⁹ dyne/cm².

In example embodiments, the first passivation layer may have a thickness ranging from about 400 Å to about 600 Å.

In example embodiments, the second passivation layer may have a thickness ranging from about 4,000 A to about 6,000 A.

According to example embodiments, there is provided a method of manufacturing a semiconductor device. In the method, a transistor and a capacitor are formed on a semiconductor wafer. An upper insulation layer which covers the transistor and the capacitor is formed. A first passivation layer is formed on the upper insulation layer by a plasma enhanced chemical vapor deposition (PECVD) process. A second passivation layer which has a compressive property is formed on the first passivation layer by a PECVD process.

In example embodiments, the second passivation layer may be formed in conditions of a higher power, a lower flow rate of a reaction gas and a lower pressure than used in a formation of the first passivation layer.

In example embodiments, the first passivation layer may be formed with a power ranging from about 400 W to about 800 W, and the second passivation layer may be formed with a power of about 1,200 W to about 1,400 W.

In example embodiments, the first passivation layer may be formed with a pressure ranging from about 3 torr to about 4 torr, and the second passivation layer may be formed with a pressure of about 1.5 torr to about 2.2 torr.

In example embodiments, the first passivation layer and the second passivation layer may be formed in a same process chamber in-situ.

In example embodiments, the PECVD process may be performed using silane and ammonia as a reaction gas.

In example embodiments, in the formation of the first passivation layer and the forming the second passivation layer, n number of semiconductor wafers, each of which includes the transistor, the capacitor and the upper insulation layer formed thereon may be loaded on a loading plate of the process chamber. The first passivation layer may be formed on each of the semiconductor wafers. The second passivation layer may be formed through stations of (n−1) times. Each of the stations may be defined by 1/(n−1) rotation of the loading plate. The semiconductor wafers including the first passivation layer and the second passivation layer formed thereon may be unloaded. Here, n is a positive integer ranging from 3 to 8.

In example embodiments, n is 4. The first passivation layer may be formed through a single station. The second passivation layer may be formed through the stations of 3 times (e.g., three 90 degree rotations). The first passivation layer may have a thickness ranging from about 400 A to about 2,000 A, and the second passivation layer may have a thickness ranging from about 4,000 A to about 6,000 A.

In example embodiments, the first passivation layer may have a thickness ranging from about 400 A to about 600 A.

According to example embodiments, there is provided a method of manufacturing a semiconductor device. In the method, a plurality of wafers having transistors and capacitors thereon is loaded in a process chamber. A first silicon nitride layer is deposited over the transistors and capacitors. Plates loaded with the plurality of wafers are rotated. A first deposition of a second nitride layer is performed over the first nitride layer. The plates loaded with the plurality of wafers are rotated. A second deposition of the second nitride layer is performed over the second nitride layer. The plurality of wafers is unloaded.

In example embodiments, the first silicon nitride layer may have a refresh property greater than that of the second nitride layer.

In example embodiments, the first silicon nitride layer may have a thickness less than that of the second nitride layer.

In example embodiments, the method may be performed in a PECVD chamber.

According to an example embodiment, a passivation layer structure covering a semiconductor device may include a first passivation layer having an excellent refresh property and a second passivation layer having an excellent compressive property. Therefore, the semiconductor device may be efficiently protected from external environment and/or shock while maintaining operational characteristics thereof.

### BRIEF DESCRIPTION OF THE DRAWINGS

Example embodiments will be more clearly understood from the following detailed description taken in conjunction with the accompanying drawings. FIGS. 1 to 28 represent non-limiting, example embodiments as described herein.

FIG. 1 is a cross-sectional view illustrating a semiconductor device in accordance with example embodiments;

FIGS. 2 and 9 are cross-sectional views illustrating a method of manufacturing a semiconductor device in accordance with example embodiments:

FIG. 10 is a cross-sectional view illustrating a semiconductor device in accordance with some example embodiments;

FIGS. 11 to 19 are cross-sectional views illustrating a method of manufacturing a semiconductor device in accordance with some example embodiments;

FIG. 20 is a flow chart illustrating a deposition process for forming a passivation layer in accordance with example embodiments;

FIGS. 21 to 25 are schematic views illustrating a deposition process for forming a passivation layer in accordance with example embodiments;

FIGS. 26 to 27 are graphs showing compressive forces of a passivation layer measured in relation to powers and pressures applied to a process chamber according to an example embodiment; and

FIG. 28 is a graph showing the number of fail bits measured with passivation layers of Examples.

### DESCRIPTION OF EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept. Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

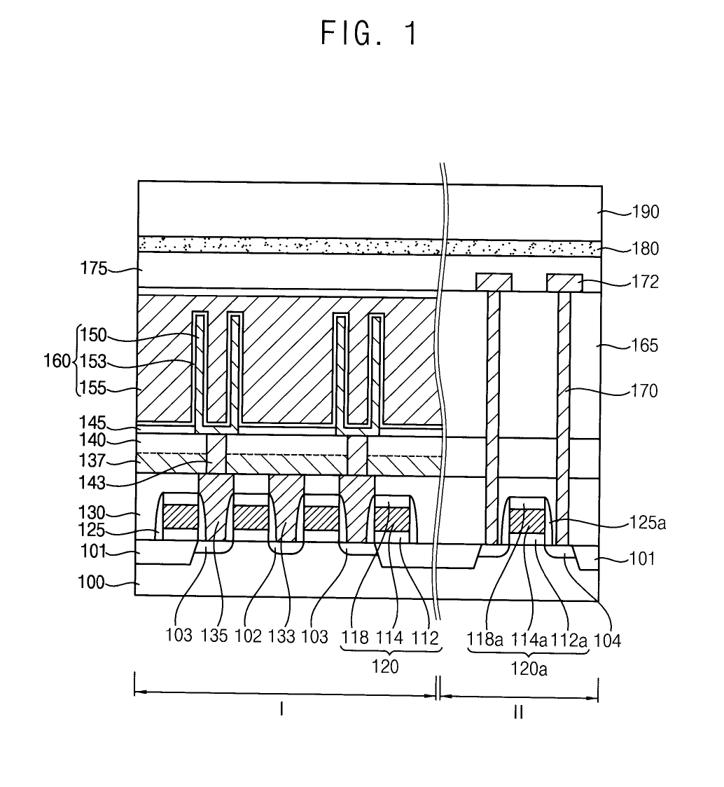

FIG. 1 is a cross-sectional view illustrating a semiconductor device in accordance with example embodiments. For example, FIG. 1 illustrates a dynamic random access memory (DRAM) device.

Referring to FIG. 1, the semiconductor device may include a transistor on a substrate 100, a capacitor 160 electrically connected to the transistor, and an upper insulation layer covering structures including the capacitor 160. A first passivation layer 180 and a second passivation layer 190 may be sequentially formed on the upper insulation layer 175 to cover or encapsulate the semiconductor device.

The substrate 100 may be prepared from a single crystalline silicon wafer or a single crystalline germanium wafer. P-type or n-type wells may be formed at an upper portion of the substrate 100.

The substrate 100 may be divided into a first region I and a second region II. In example embodiments, the first region I and the second region II may serve as a cell region and a peripheral circuit region, respectively. The substrate 100 may be also divided into an active region and a field region by an isolation layer 101.

A first gate structure 120 may be disposed on the first region I of the substrate 100. The first gate structure 120 may include a first gate insulation layer pattern 112, a first gate electrode 114 and a first gate mask 118 sequentially stacked from a top surface of the substrate 100. A first gate spacer 125 may be formed on a sidewall of the first gate structure 120.

A second gate structure 120a may be disposed on the second region II of the substrate 100. The second gate structure 120a may include a second gate insulation layer pattern 112a, a second gate electrode 114a and a second gate mask 118a sequentially stacked from the top surface of the substrate 100. A second gate spacer 125a may be formed on a sidewall of the second gate structure 120a.

The first and second gate insulation layer patterns 112 and 112a may include silicon oxide or a metal oxide. The first and second gate electrodes 114 and 114a may include a metal, a metal nitride or doped polysilicon. The first and second gate masks 118 and 118a, and the first and second gate spacers 125 and 125a may include silicon nitride or silicon oxynitride.

A first impurity region 102 and a second impurity region 103 may be formed at upper portions of the substrate 100 adjacent to the first gate structures 120. A third impurity region 104 may be formed at upper portions of the substrate 100 adjacent to the second gate structure 120a.

A cell transistor may be defined on the first region I by the first gate structure 120, the first impurity region 102 and the second impurity region 103. A peripheral circuit transistor may be defined on the second region II by the second gate structure 120a and the third impurity region 104.

A first insulating interlayer 130 covering the first and second gate structures 120 and 120a may be formed on the substrate 100. The first insulating interlayer 130 may include silicon oxide, e.g., plasma enhanced oxide (PEOX), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), etc.

A first plug 133 and a second plug 135 may be formed through the first insulating interlayer 130 to be in contact with the first impurity region 102 and the second impurity region 103, respectively. The first plug 133 may serve as a bit line contact.

A bit line 137 may be disposed on the first insulating interlayer 130 to be in contact with the first plug 133. A second insulating interlayer 140 covering the bit line 137 may be formed on the first insulating interlayer 130. The second insulating interlayer 140 may include silicon oxide substantially the same as or similar to that of the first insulating interlayer 130.

A third plug 143 may be formed through the second insulating interlayer 140 to be in contact with the second plug 135. The third plug 143 may serve as a capacitor contact. In one example embodiment, the third plug 143 may be formed through the second insulating interlayer 140 and the first insulating interlayer 130 to be in contact with the second impurity region 103. In this case, the second plug 135 may be omitted.

The first to third plugs 133, 135 and 143, and the bit line 137 may include, e.g., a metal, a metal nitride or doped polysilicon.

An etch-stop layer 145 may be formed on a portion of the second insulating interlayer 140 on the first region I. A top surface of the third plug 143 may be exposed by the etch-stop layer 145. A lower electrode 150 may be disposed on the second insulating interlayer 140 and the third plug 143 exposed by the etch-stop layer 145.

A dielectric layer 153 may be formed on the lower electrode 150 and the etch-stop layer 145, and an upper electrode 155 may be disposed on the dielectric layer 153. The capacitor 160 may be defined by the lower electrode 150, the dielectric layer 153 and the upper electrode 155.

The etch-stop layer 145 may include silicon nitride. The lower electrode 150 and the upper electrode 155 may include a metal or a metal nitride. The dielectric layer 153 may include a metal oxide having a high dielectric constant.

A third insulating interlayer 165 may be formed on the capacitor 160 of the first region I, and the second insulating interlayer 140 of the second region II. The third insulating interlayer 165 may include the above-mentioned silicon oxide.

A contact 170 may be disposed on the second region II to extend through the first to third insulating interlayers 130, 140 and 165. The contact 170 may be in contact with the third impurity region 104. A wiring 172 may be electrically connected to the contact 170 on the third insulating interlayer 165. The wiring 172 and the contact 170 may be a portion of a peripheral circuit provided on the second region II. The wiring 172 and the contact 170 may include a metal, a metal nitride and doped polysilicon.

The upper insulation layer 175 may be formed on the third insulating interlayer 165 to cover the wiring 172. The upper insulation layer 175 may protect the peripheral circuit including the wiring 172.

The first passivation layer 180 and the second passivation layer 190 may be formed on the upper insulation layer 175. The first and second passivation layers 180 and 190 may cover the first and second regions I and II of the substrate 100 to encapsulate the DRAM device. The first and second passivation layers 180 and 190 may include silicon nitride, however, may have physical and/or chemical layer properties different from those of each other.

In example embodiments, the first passivation layer 180 may serve as a barrier layer that may block a leakage charge or a leakage current from the capacitor 160. In a volatile semiconductor device, e.g., the DRAM device, a refresh cycle by which charges accumulated in the capacitor are discharged, and then recharged may be repeated. If the charges are leaked from the capacitor or the DRAM device, the leakage current may be caused to deteriorate a refresh property of the DRAM device.

The first passivation layer 180 may suppress the charges stored in the capacitor 160 from being leaked to prevent or reduce a generation of the leakage current. Accordingly, the first passivation layer 180 may improve a gate-induced drain leakage (GIDL) property of the DRAM device so that the refresh property of the DRAM device may be enhanced.

The second passivation layer 190 may serve as a compressing layer to compensate or correct a warpage of the substrate 100. In the case that a silicon wafer is utilized as the substrate 100, a back surface of the silicon wafer may be polished by, e.g., a back-lapping process to reduce a chip thickness. In this case, the silicon wafer may be vulnerable to a U-type warpage by a tensile strength imposed thereon. The second passivation layer 190 may provide a compressive stress to the silicon wafer having the U-type warpage to correct or compensate the warpage of the wafer.

The above mentioned GIDL or refresh properties and a compressive property of the passivation layer may be in a trade-off relation. For example, when the compressive property of the passivation layer is increased, the leakage current may not be sufficiently suppressed by the passivation layer to deteriorate the refresh property of the DRAM device. In contrast, when the refresh property of the passivation layer is increased, the compressive property of the passivation layer may be reduced so that the DRAM device may be vulnerable to the warpage.

Thus, when the passivation layer is formed as a single-layered structure, either of the refresh and compressive properties may not be sufficiently achieved to result in a refresh failure or an excessive warpage.

In example embodiments, the passivation layer may be formed as a double-layered structure to improve the refresh property and prevent or reduce the warpage of the substrate. As described above, the first passivation layer 180 may have the refresh property for blocking the leakage charge and/or the leakage current, and the second passivation layer 190 may have the compressive property for suppressing the warpage of the wafer.

In example embodiments, a thickness of the first passivation layer 180 may range from about 400 Å to about 2,000 Å. If the thickness of the first passivation layer 180 is less than about 400 Å, the leakage current or the leakage charge may not be sufficiently suppressed. Even though the thickness of the first passivation layer 180 exceeds about 2,000 Å, the refresh property may not be further increased and a process cost may be increased. In one example embodiment, the thickness of the first passivation layer 180 may range from about 400 Å to about 600 Å.

A thickness of the second passivation layer 190 may range from about 2,000 Å to about 10,000 Å. If the thickness of the second passivation layer 190 is less than about 2,000 Å, the warpage of the substrate 100 or the wafer may not be sufficiently prevented or compensated. If the thickness of the second passivation layer 190 exceeds about 10,000 Å, a process cost and a total height of the semiconductor device may be increased. In one example embodiment, the thickness of the second passivation layer 190 may range from about 4,000 Å to about 6,000 Å.

In one example embodiment, the second passivation layer 190 may have a layer density greater than that of the first passivation layer 180. As the layer density becomes larger, the compressive property may be increased. Thus, the second passivation layer 190 may be formed to have the relatively large layer density.

In one example embodiment, the first passivation layer 180 may have a hydrogen content greater than that of the second passivation layer 190. As the hydrogen content in the passivation layer becomes larger, hydrogen atoms may cure defects in insulation or conductive layers under the passivation layer so that the refresh property of the passivation layer may be improved. Thus, the first passivation layer 180 may be formed to have the relatively large hydrogen content.

As described above, the passivation layer of, e.g., the DRAM device may be formed as a double-layered structure to improve the refresh property and to prevent or reduce the warpage. Therefore, electrical and structural reliability of the DRAM device may be enhanced.

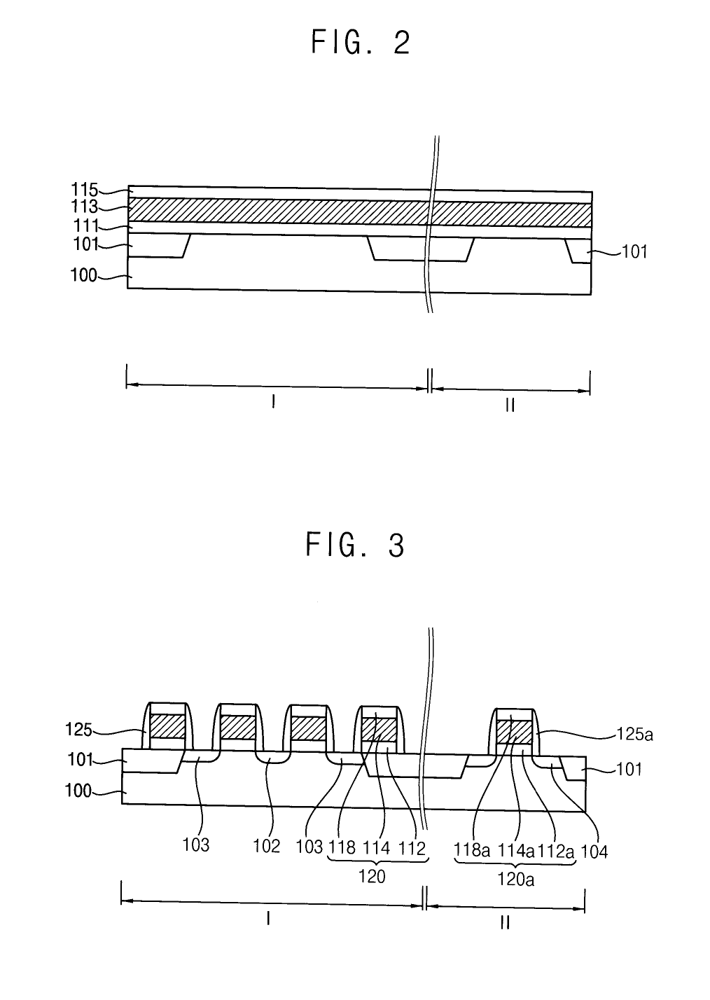

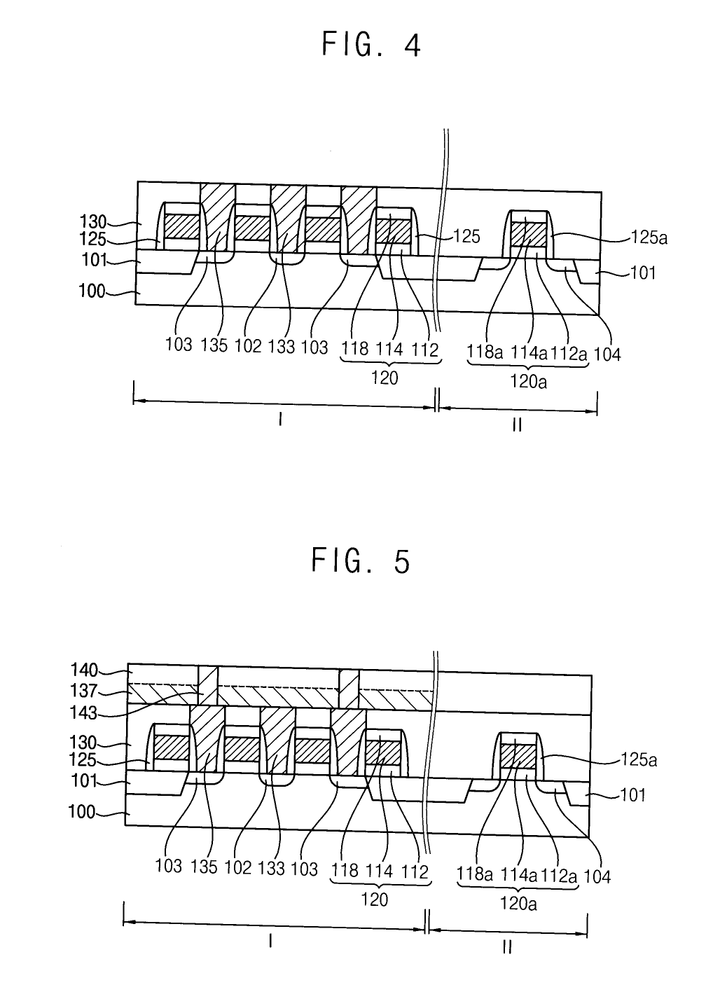

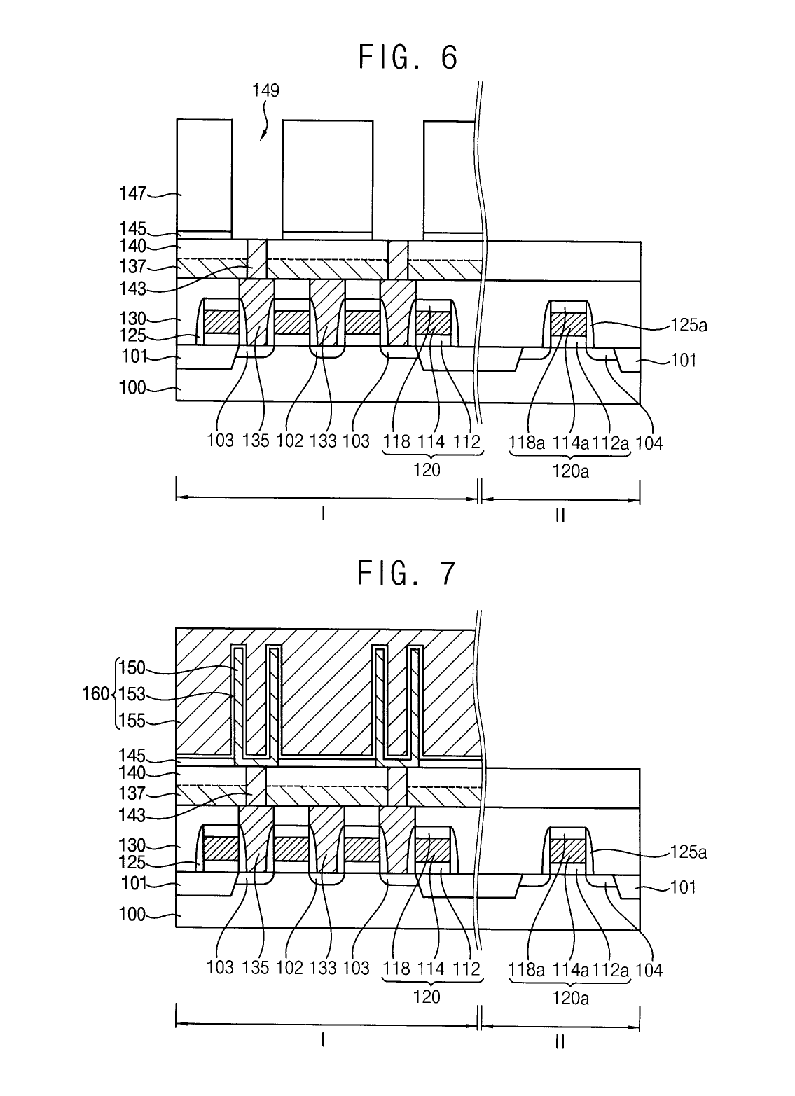

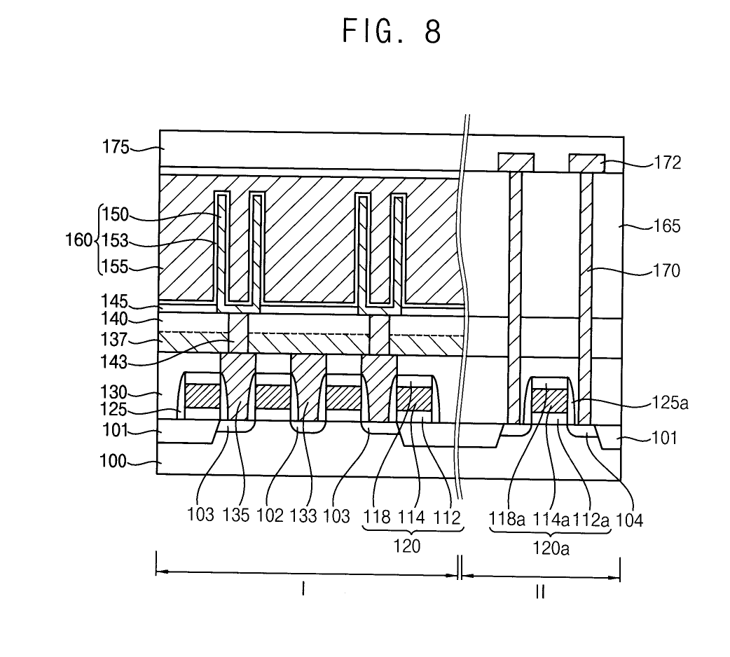

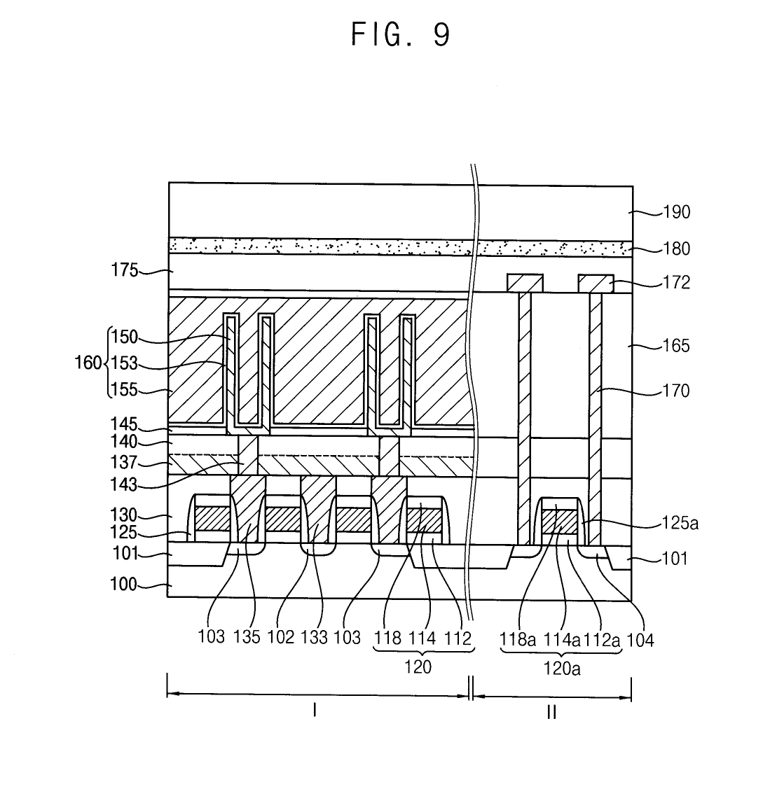

FIGS. 2 and 9 are cross-sectional views illustrating a method of manufacturing a semiconductor device in accordance with example embodiments. For example, FIGS. 2 to 9 illustrate a method of manufacturing the semiconductor device of FIG. 1.

Referring to FIG. 2, a gate insulation layer 111, a gate electrode layer 113 and a mask layer 115 may be sequentially formed on a substrate 100.

The substrate 100 may be prepared from a single crystalline silicon wafer or a single crystalline germanium wafer. The substrate 100 may include a first region I and a second region II. The first region I and the second region II may correspond to a cell region and a peripheral circuit region, respectively.

An isolation layer 101 may be formed at an upper portion of the substrate by, e.g., a shallow trench isolation (STI) process. The substrate 100 may be divided into an active region and a field region by the isolation layer 101, respectively.

The gate insulation layer 111 may be formed using silicon oxide and a metal oxide by, e.g., a chemical vapor deposition (CVD) process or a spin coating process. In one example embodiment, the gate insulation layer 111 may be formed by performing a thermal oxidation process on a top surface of the substrate 100.

The gate electrode layer 113 may be formed using a metal and/or a metal nitride, e.g., tungsten (W), tungsten nitride, titanium (Ti), titanium nitride, aluminum or aluminum nitride. The gate electrode layer 113 may be formed by, e.g., an atomic layer deposition (ALD) process, a sputtering process or a physical vapor deposition (PVD) process. In one example embodiment, the gate electrode layer 113 may be formed using doped polysilicon.

The mask layer 115 may be formed using silicon nitride or silicon oxynitride by, e.g., a CVD process or a spin coating process.

Referring to FIG. 3, the mask layer 115, the gate electrode layer 113 and the gate insulation layer 111 may be partially etched to form a first gate structure 120 and a second gate structure 120a on the first region I and the second region II, respectively.

For example, the mask layer 115 may be partially etched to form a first gate mask 118 and a second gate mask 118a on the first region I and the second region II, respectively. The gate electrode layer 113 and the gate insulation layer 111 may be patterned using the first and second gate masks 118 and 118a as an etching mask. Accordingly, the first gate structure 120 including a first gate insulation layer pattern 112, a first gate electrode 114 and a first gate mask 118 may be formed on the first region I. The second gate structure 120a including a second gate insulation layer pattern 112a, a second gate electrode 114a and a second gate mask 118a may be formed on the second region II.

An ion implantation process may be performed using the gate structures 120 and 120a as an implantation mask to form impurity regions at upper portions of the substrate 100 adjacent to the gate structures 120 and 120a. First and second impurity regions 102 and 103 may be formed at the upper portions of the substrate 100 on the first region I. A third impurity region 104 may be formed at the upper portion of the substrate 100 on the second region II.

A cell transistor may be defined on the first region I by the first gate structure 120, the first impurity region 102 and the second impurity region 103. A peripheral circuit transistor may be defined on the second region II by the second gate structure 120a and the third impurity region 104. The first to third impurity regions 102, 103 and 104 may serves as source/drain regions of the transistors.

A first gate spacer 125 and a second gate spacer 125a may be further formed on a sidewall of the first gate structure 120 and the second gate structure 120a. For example, a spacer layer covering the first and second gate structures 120 and 120a may be formed on the substrate 100. The spacer layer may be anisotropically etched to form the first and second gate spacers 125 and 125a. The spacer layer may be formed using silicon nitride or silicon oxynitride by, e.g., a CVD process or a spin coating process.

Referring to FIG. 4, a first insulating interlayer 130 covering the first and second gate structures 120 and 120a may be formed on the substrate. The first insulating interlayer 130 may be formed using silicon oxide such as PEOX, BTEOS, PTEOS, BPTEOS, BSG, PSG or BPSG by, e.g., a CVD process.

A first plug 133 and a second plug 135 may be formed through the first insulating interlayer 130 to contact the first impurity region I and the second impurity region II, respectively.

For example, a portion of the first insulating interlayer 130 may be partially removed to form first holes through which the first and second impurity regions 102 and 103 are exposed. A first conductive layer filling the first holes may be formed on the first insulating interlayer 130, and then an upper portion of the first conductive layer may be planarized until a top surface of the first insulating interlayer 130 is exposed to form the first and second plugs 133 and 135.

The first conductive layer may be formed using a metal such as tungsten, copper or aluminum and/or a nitride thereof by, e.g., a sputtering process, an ALD process or a PVD process. The planarization process may include a CMP process or an etch-back process.

Referring to FIG. 5, a bit line 137 electrically connected to the first plug 133 may be formed. For example, a second conductive layer may be formed on the first insulating interlayer 130 to be in contact with the first plug 133. The second conductive layer may be patterned to form the bit line 137. The first plug 133 may serve as a bit line contact.

A second insulating interlayer 140 covering the bit line 137 may be formed on the first insulating interlayer 130. The second insulating interlayer 140 may be formed throughout the first and second regions I and II. The second insulating interlayer 140 may be formed using the above-mentioned silicon oxide by, e.g., a CVD process or a spin coating process.

A third plug may be formed through the second insulating interlayer 140 to be electrically connected to the second plug 135. For example, the second insulating interlayer 140 may be partially etched to form a second hole through which a top surface of the second plug 135 is exposed. A third conductive layer filling the second hole may be formed on the second insulating interlayer 140. An upper portion of the third conductive layer may be planarized until a top surface of the second insulating interlayer 140 is exposed to form the third plug 143.

The third plug 143 may serve as a capacitor contact of the DRAM device together with the second plug 135. In one example embodiment, the formation of the second plug 135 may be omitted, and the third plug 143 may be formed through the second and first insulating interlayers 140 and 130 to contact the second impurity region 103. In this case, the third plug 143 may solely serve as the capacitor contact.

The second and third conductive layers may be formed using a metal and/or a metal nitride by a sputtering process, an ALD process, a PVD process, etc.

Referring to FIG. 6, an etch-stop layer 145 and a mold layer 147 may be sequentially formed on the second insulating interlayer 140. The mold layer 147 and the etch-stop layer 145 may be partially etched to form an opening 149 through which a top surface of the third plug 143 is exposed on the first region I. A portion of the mold layer 147 and the etch-stop layer 145 formed on the second region II may be removed by the etching process.

Referring to FIG. 7, a capacitor 160 may be formed on the second insulating interlayer 140 and the third plug 143.

For example, a lower electrode layer may be formed along an innerwall of the opening 149 and a top surface of the mold layer 147. A sacrificial layer (not illustrated) may be formed on the lower electrode layer, and then portions of the sacrificial layer and the lower electrode layer may be removed until the top surface of the mold layer 147 is exposed. The sacrificial layer and the mold layer 147 may be removed by a wet etching process using, e.g., a hydrofluoric acid solution or a buffer oxide etchant (BOE) solution to form the lower electrode 150 electrically connected to the third plug 143.

A dielectric layer 153 may be formed along surfaces of the etch-stop layer 145 and the lower electrode 150, and an upper electrode layer may be formed on the dielectric layer 153. Portions of the dielectric layer 153 and the upper electrode layer formed on the second region II may be removed to form an upper electrode 155 on the first region I.

The lower and upper electrode layers may be formed using a metal and/or a metal nitride by, e.g., a sputtering process, an ALD process, a PVD process, etc. The dielectric layer 153 may be formed using a metal oxide of a high dielectric constant, e.g., hafnium oxide or zirconium oxide by, e.g., a CVD process or an ALD process.

Accordingly, the capacitor 160 including the lower electrode 150, the dielectric layer 153 and the upper electrode 155 may be formed on the first region I.

Referring to FIG. 8, a third insulating interlayer 165 covering the capacitor 160 may be formed on the second insulating interlayer 140. The third insulating interlayer 165 may be formed throughout the first and second regions I and II. A planarization process, e.g., a CMP process may be further performed on a top surface of the third insulating interlayer 165.

A contact 170 and a wiring 172 electrically connected to the peripheral circuit transistor may be formed on the second region II of the substrate 100. For example, a third hole may be formed through the third to first insulating interlayers 165, 140 and 130 to expose the third impurity region 104. A fourth conductive layer filling the third hole may be formed on the third insulating interlayer 165. An upper portion of the fourth conductive layer may be planarized to form the contact 170 electrically connected to the third impurity region 104. A fifth conductive layer may be formed on the third insulating interlayer 165 and may be patterned by a photolithography process to form the wiring 172 in contact with the contact 170. The contact 170 and the wiring 172 may serve as a portion of a peripheral circuit.

An upper insulation layer 175 may be formed on the third insulating interlayer 165 to cover the contact 170 and the wiring 172.

The third insulating interlayer 165 and the upper insulation layer 175 may be formed using the above-mentioned silicon oxide by, e.g., a CVD process or a spin coating process. The fourth and fifth conductive layers may be formed using a metal and/or a metal nitride by, e.g., a sputtering process or an ALD process.

Referring to FIG. 9, a first passivation layer 180 and a second passivation layer 190 may be formed on the upper insulation layer 175. The first and second passivation layers 180 and 190 may cover both first and second regions I and II of the substrate. In one example embodiment, the first and second passivation layers 180 and 190 may encapsulate the DRAM device.

In example embodiments, the first and second passivation layers 180 and 190 may be formed using silicon nitride by a plasma enhanced vapor deposition (PECVD) process. In an example embodiment, silane (SiH₄) and ammonia (NH₃) may be used as a reaction gas.

As described with reference to FIG. 1, the first passivation layer 180 may be formed to have superior refresh property and leakage block property. The second passivation layer 190 may be formed to have a compressive property to prevent or reduce a warpage of the substrate 100 due to a tensile strength.

The first and second passivation layers 180 and 190 may be formed by the PECVD process in the same process chamber varying process conditions in-situ.

In example embodiments, the second passivation layer 190 may be formed in a process condition of a higher radiofrequency (RF) power, a lower flow rate of the reaction gas and a lower pressure than those in a formation of the first passivation layer 180.

If the PECVD process is performed using a high RF power, ions contained in the reaction gas may be collided or bombarded in a faster rate. Thus, a bonding energy of a compound formed from the ions may be increased so that a layer density may be also increased.

In the case that the flow rate of the reaction gas and the pressure in the process chamber are maintained at low levels, a concentration of the reaction gas may be reduced. Accordingly, a mean free path of the ions may be increased, and thus a collision rate of the ions may be also increased. Thus, a layer density may be increased.

The second passivation layer 190 may be formed in the process condition of a high power, a low flow rate and a low pressure to have a layer density greater than that of the first passivation layer 180.

When the PECVD process is performed in the process condition for obtaining the high layer density, collision rate or energy of ions may be increased so that hydrogen atoms may be released from hydrogen bondings (e.g., Si—H or N—H bondings) that may have a relatively low bonding force. Thus, the second passivation layer 190 may have a hydrogen content lower than that of the first passivation layer 180.

When the hydrogen content in a layer is decreased, a GIDL property of the layer may be deteriorated to cause a leakage current and the low refresh property. In example embodiments, the first passivation layer 180 may be formed in a lower density condition than that in a formation of the second passivation layer 190 to have the relatively high hydrogen content. Thus, the passivation layer 180 may have the greater refresh property than that of the second passivation layer 190.

In example embodiments, the first passivation layer 180 may be formed in a power condition ranging from about 400 W to about 800 W. In one example embodiment, the first passivation layer 180 may be formed in a power condition ranging from about 600 W to about 800 W. The second passivation layer 190 may be formed in a power condition ranging from about 1,200 W to about 1,400 W.

The first passivation layer 180 may be formed in a pressure condition ranging from about 3 torr to about 4 torr. In one example embodiment, the first passivation layer 180 may be formed in a pressure condition ranging from about 3.0 torr to about 3.5 torr. The second passivation layer 190 may be formed in a pressure condition ranging from about 1.5 torr to about 2.2 torr.

In example embodiments, the second passivation layer 190 may have a compressive force greater than about 6.0×10⁹ dyne/cm² (represented by an absolute value). In one example embodiment, the second passivation layer 190 may have a compressive force ranging from about 6.0×10⁹ dyne/cm² to about 9.0×10⁹ dyne/cm². If the compressive force of the second passivation layer 190 is less than about 6.0/×10⁹ dyne/cm², the warpage of the substrate 100 may not be sufficiently compensated by the second passivation layer 190. If the compressive force of the second passivation layer exceeds about 9.0>10⁹ dyne/cm², a reverse warpage may occur due to the excessive compressive force.

The first passivation layer 180 may have a compressive force less than about 2.0×10⁹ dyne/cm². In one example embodiment, the first passivation layer 180 may have a compressive force ranging from about 1.0>10⁹ dyne/cm² to about 2.0×10⁹ dyne/cm². In this case, the first passivation layer 180 may have a predetermined compressive force level in which the refresh property of the first passivation layer 180 may not be deteriorated.

The compressive force of the passivation layer may be proportional to a thickness of the passivation layer. As the thickness of the passivation layer becomes larger, the leakage block property of the passivation layer may be also increased. However, the leakage block property may not be increased when the thickness of the passivation layer is over a specific critical thickness.

In example embodiments, a thickness of the first passivation layer 180 may range from about 400 Å to about 2,000 Å. If the thickness of the first passivation layer 180 is less than about 400 Å, the sufficient leakage block property may not be achieved. If the thickness of the first passivation layer 180 is greater than about 2,000 Å, the leakage block property thereof may not be further increased and a process cost may be increased. In one example embodiment, the first passivation layer 180 may have a thickness ranging from about 400 Å to about 600 Å.

A thickness of the second passivation layer 190 may range from about 2,000 Å to about 10,000 Å. If the thickness of the second passivation layer 190 is less than about 2,000 Å, the warpage of the substrate 100 or the wafer may not be sufficiently prevented or compensated. If the thickness of the second passivation layer 190 exceeds about 10,000 Å, a process cost and a total height of the semiconductor device may be increased. In one example embodiment, the thickness of the second passivation layer 190 may range from about 4,000 Å to about 6,000 Å.

As described above, the passivation layer of, e.g., the DRAM device may be formed as a double-layered structure to improve the refresh property and to prevent or reduce the warpage. According to example embodiments, the first passivation layer 180 targeted to improve the refresh property and the second passivation layer 190 targeted to prevent or reduce the warpage may be formed in the process conditions different from those of each other. Thus, desired properties including the refresh property and the compressive property may be achieved in the passivation layer structure.

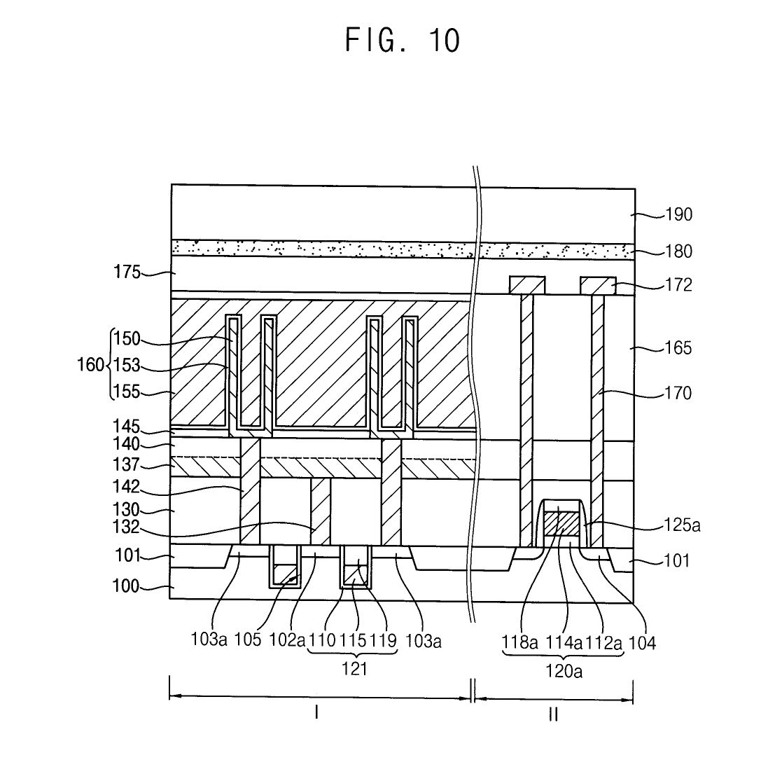

FIG. 10 is a cross-sectional view illustrating a semiconductor device in accordance with some example embodiments. For example, FIG. 10 illustrates a DRAM device including a buried gate structure.

Detailed descriptions on elements and/or constructions substantially the same as or similar to those illustrated with reference to FIG. 1 are omitted. Like reference numerals are used to indicate like elements.

Referring to FIG. 10, a cell transistor including a first gate structure 121, a first impurity region 102a and a second impurity region 103a may be formed on a first region I of a substrate. A capacitor 160 may be formed on the first region I to be electrically connected to the cell transistor. A peripheral circuit transistor including a second gate structure 120a and a third impurity region 104 may be formed on a second region II of the substrate 100. A contact 170 and a wiring 172 electrically connected to the peripheral circuit transistor may be disposed on the second region II.

In example embodiments, a gate electrode of the first gate structure 121 may be at least partially buried or embedded in the substrate 100. Thus, a channel area of the substrate 100 may be expanded.

As illustrated in FIG. 10, a recess 105 may be formed at an upper portion of the substrate 100 in the first region I. A first gate insulation layer pattern 110 may be formed on an innerwall of the recess 105. A first gate electrode 115 partially filling the recess 105 may be formed on the first gate insulation layer pattern 110. A first gate mask 119 capping the recess 105 may be formed on the first gate electrode 115. The first gate structure 121 having the buried gate structure may be defined by the first gate insulation layer pattern 110, the first gate electrode 115 and the first gate mask 119.

In one example embodiment, the first gate electrode 115 may be partially buried or embedded in the substrate 100. In this case, a portion of the first gate electrode 115 may be buried in the substrate 100, and a remaining portion of the first gate electrode 115 may protrude from a top surface of the substrate 100. The first gate mask 119 may be formed on the remaining portion of the first gate electrode 115.

First and second impurity regions 102a and 103a may be formed at upper portions of the substrate 100 adjacent to the first gate structure 121.

The second gate structure 120a on the second region II of the substrate 100 may have a structure substantially the same as or similar to that illustrated in FIG. 1. In one example embodiment, the second gate structure 120a may also have the buried gate structure.

A bit line contact 132 may be formed through a first insulating interlayer 130 to contact the first impurity region 102a. A bit line 137 may be disposed on the first insulating interlayer 130 to be electrically connected to the bit line contact 132.

A capacitor contact 142 may be formed through the first insulating interlayer 130 and a second insulating interlayer 140 to contact the second impurity region 103a. The capacitor 160 may be formed on the second insulating interlayer 140 to be electrically connected to the capacitor contact 142.

The contact 170 may be formed through a third insulating interlayer 165, the second insulating interlayer 140 and the first insulating interlayer 130 to be electrically connected to the third impurity region 104. The wiring 172 may be disposed on the third insulating interlayer 165 to be electrically connected to the contact 170.

An upper insulation layer 175 may be formed on the third insulating interlayer 165 to cover the wiring 172. As described in FIG. 1, first and second passivation layers 180 and 190 may be formed on the upper insulation layer 175 so that a refresh property of the DRAM device may be improved while suppressing a warpage of the substrate 100.

FIGS. 11 to 19 are cross-sectional views illustrating a method of manufacturing a semiconductor device in accordance with some example embodiments. For example, FIGS. 11 to 19 illustrate a method of manufacturing the semiconductor device of FIG. 10.

Detailed descriptions on processes and/or materials substantially the same as or similar to those illustrated with reference to FIGS. 2 to 9 are omitted.

Referring to FIG. 11, an ion implantation process may be performed on a substrate 100 of a first region I to form a preliminary impurity region 106. An isolation layer 101 may be formed by, e.g., an STI process so that the substrate 100 may be divided into an active region and a field region.

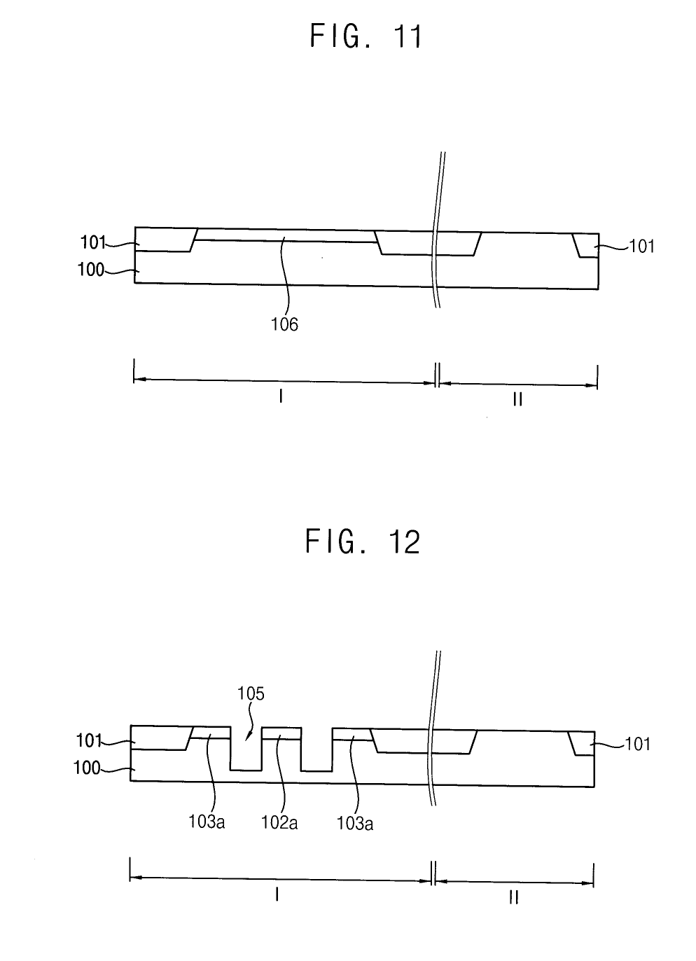

Referring to FIG. 12, an upper portion of the substrate 100 may be partially removed to form a recess 105 on the first region I. For example, a mask pattern (not illustrated) partially exposing a top surface of the substrate 100 on the first region I may be formed. A dry etching process may be performed using the mask pattern to form the recess 105. The mask pattern may be removed by an ashing process and/or a strip process. The preliminary impurity region 106 may be divided into a first impurity region 102a and a second impurity region 103a by the formation of the recess 105.

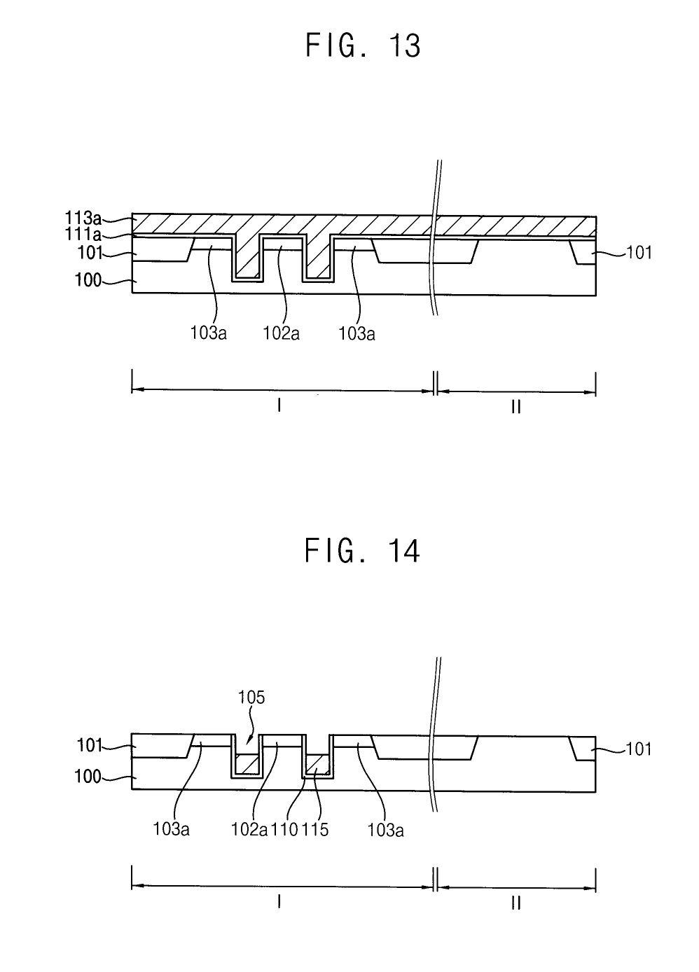

Referring to FIG. 13, a first gate insulation layer 111a may be formed on the top surface of the substrate 100 and an innerwall of the recess 105, and a first gate electrode layer 113a filling the recess 105 may be formed on the first gate insulation layer 111a.

Referring to FIG. 14, upper portions of the first gate insulation layer 111a and the first gate electrode layer 113a may be removed to form a first gate insulation layer pattern 110 and a first gate electrode 115.

For example, the gate insulation layer 111a and the first gate electrode layer 113a may be planarized by a CMP process until the top surface of the substrate 100 is exposed to form the first gate insulation layer pattern 110 on the innerwall of the recess 105. The upper portion of the first gate electrode layer 113a may be additionally removed by an etch-back process to form the first gate electrode 115. In example embodiments, the first gate electrode 115 may be fully buried or embedded in the recess 105 as illustrated in FIG. 14.

In one example embodiment, a portion of the first gate electrode may be buried in the recess 105, and a remaining portion of the first gate electrode may protrude from the recess 105. In this case, the first gate insulation layer pattern 110 may be formed on the innerwall of the recess 105, and then a gate electrode layer sufficiently filling the recess 105 may be formed on the substrate. The gate electrode layer may be patterned to form the first gate electrode including a protrusion.

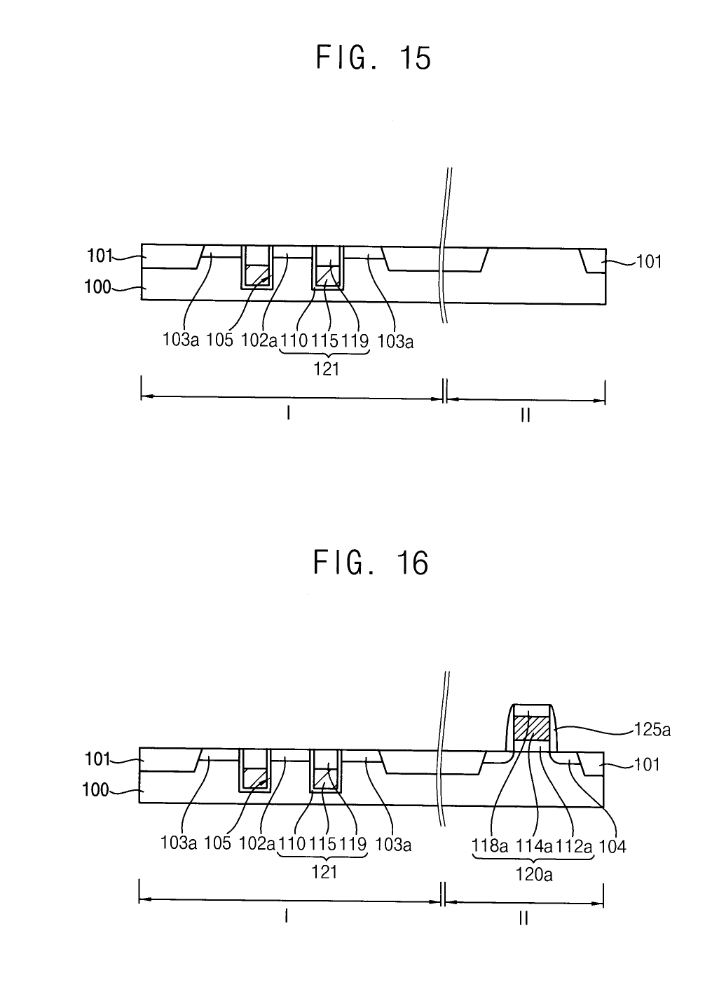

Referring to FIG. 15, a first gate mask 119 may be formed on the first gate electrode 115. For example, a first gate mask layer filling a remaining portion of the recess 105 may be formed on the substrate 100. An upper portion of the first gate mask layer may be planarized by, e.g., a CMP process to form the first gate mask 119. Accordingly, a first gate structure 121 including the first gate insulation layer pattern, the first gate electrode 115 and the first gate mask 119 and having the buried gate structure may be formed on the first region I.

Referring to FIG. 16, a second gate structure 120a may be formed on the second region II of the substrate 100. For example, a second gate insulation layer, a second gate electrode layer and a second gate mask layer may be sequentially formed on the substrate 100, and then patterned to form the second gate structure 120a including a second gate insulation layer pattern 112a, a second gate electrode 114a and a second gate mask 118a.

An ion implantation process may be performed using the second gate structure 120a as an implantation mask to form a third impurity region 104. A second gate spacer 125a may be formed on a sidewall of the second gate structure 120a.

In one example embodiment, the second gate structure may be formed to have a structure substantially the same as or similar to that of the first gate structure 121. In this case, the recess 105 may be also formed on the second region II and the second gate structure may be formed simultaneously with the first gate structure 121.

Referring to FIG. 17, a first insulating interlayer 130 covering the first and second gate structures 121 and 120a may be formed on the substrate 100. A bit line contact 132 may be formed through the first insulating interlayer 130 to contact the first impurity region 102a. A bit line 137 may be formed on the first insulating interlayer 130 to be electrically connected to the bit line contact 132.

A second insulating interlayer 140 may be formed on the first insulating interlayer 130. A capacitor contact 142 may be formed through the second insulating interlayer 140 and the first insulating interlayer 130 to contact the second impurity region 103a.

Referring to FIG. 18, processes substantially the same as or similar to those illustrated with reference to FIGS. 6 to 8 may be performed. Accordingly, a capacitor 160 electrically connected to the capacitor contact 142 may be formed on the first region I of the substrate 100. A third insulating interlayer 165 covering the capacitor 160 may be formed on the second insulating interlayer 140. A contact 170 may be formed through the third to first insulating interlayers 165, 140 and 130 to be electrically connected to the third impurity region 104 on the second region II. A wiring 172 electrically connected to the contact 170 may be formed on the third insulating interlayer 165, and an upper insulation layer 175 covering the wiring 172 may be formed on the third insulating interlayer 165.

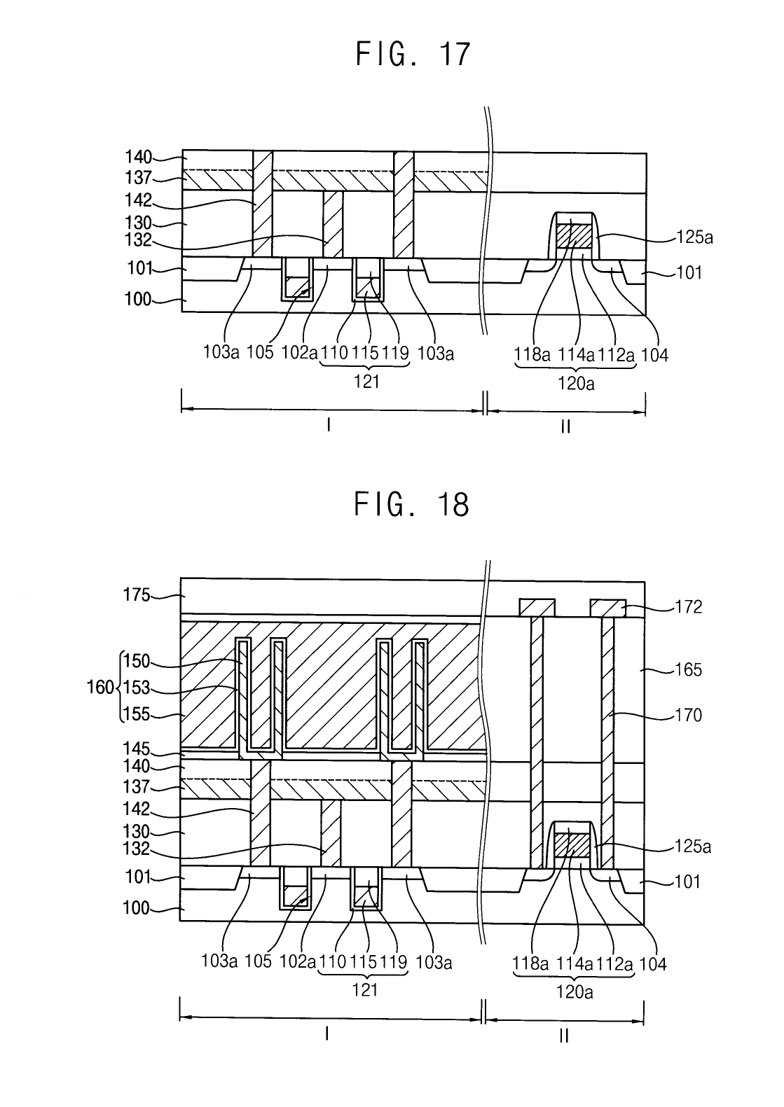

Referring to FIG. 19, a process substantially the same as or similar to that illustrated with reference to FIG. 9 may be performed. Accordingly, a first passivation layer 180 and a second passivation layer 190 may be formed on the upper insulation layer to obtain the semiconductor device.

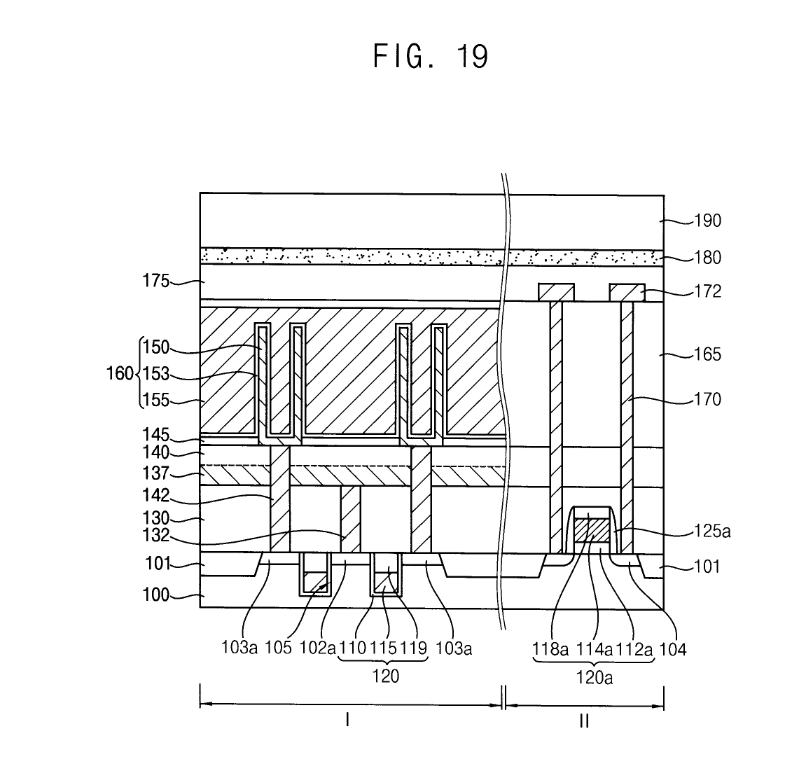

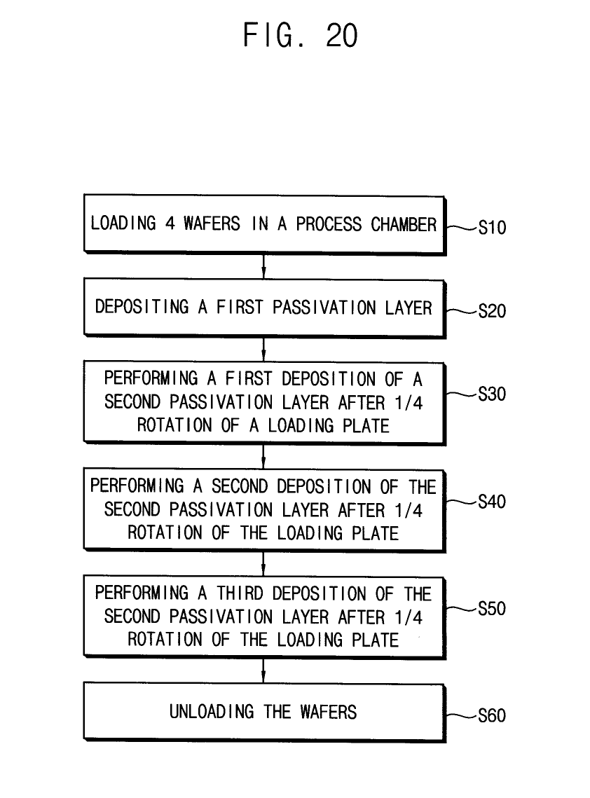

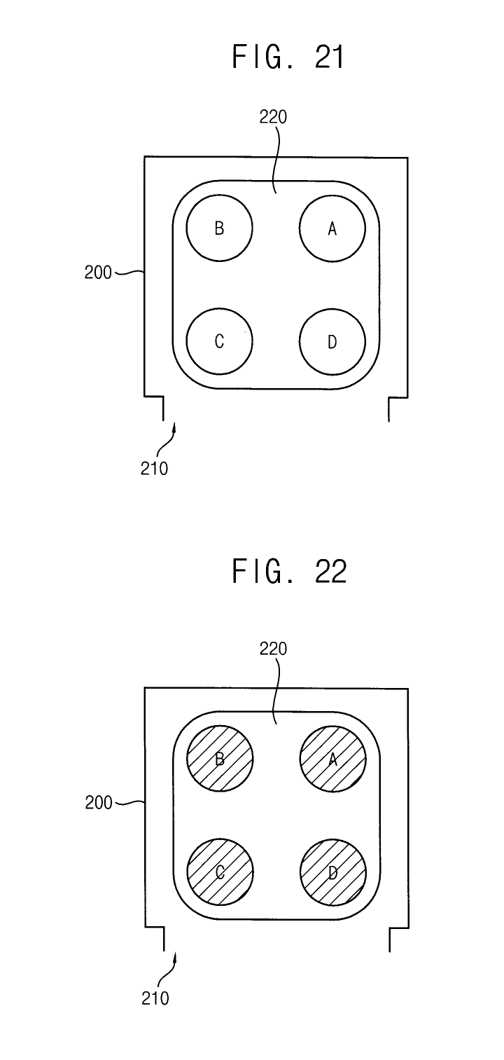

FIG. 20 is a flow chart illustrating a deposition process for forming a passivation layer in accordance with example embodiments. FIGS. 21 to 25 are schematic views illustrating a deposition process for forming a passivation layer in accordance with example embodiments.

FIGS. 20 to 25 illustrate a PECVD process for obtaining a first passivation layer of about 500 Å and a second passivation layer of about 5,400 Å. However, the thicknesses of the passivation layers are not limited to specific values.

Referring to FIGS. 20 and 21, in step S10, four wafers may be loaded on a process chamber 200.

In example embodiments, the process chamber 200 may include a chamber for a PECVD process. The process chamber 200 may include an inlet 210 through which the wafers are introduced. A loading plate 220 may be disposed in the process chamber 200. The loading plate 220 may be rotatably support the wafers, and a plurality of the wafers may be placed on the loading plate 220. The wafers may include a first wafer A, a second wafer B, a third wafer C and a fourth wafer D. A DRAM device including a transistor and a capacitor may be formed on the wafer, and an insulation layer including, e.g., silicon oxide may be formed on the wafer to cover the DRAM device.

In example embodiments, the first wafer A and the second wafer B may be loaded on the loading plate 220 through the inlet 210, and then the loading plate 220 may be rotated by about 1800 (e.g., ½ rotation of the loading plate 220). The third wafer C and the fourth wafer D may be loaded on the loading plate 220 through the inlet 210. A loading state illustrated in FIG. 21 is referred to as a first station.

Referring to FIGS. 20 and 22, in step 20, a first passivation layer may be formed in the first station. As described above, the first passivation layer may be formed in conditions of a low power, a high pressure and a high flow rate. Thus, the first passivation layer may have an excellent refresh property. For example, the first passivation layer may be formed to have a thickness of about 500 Å.

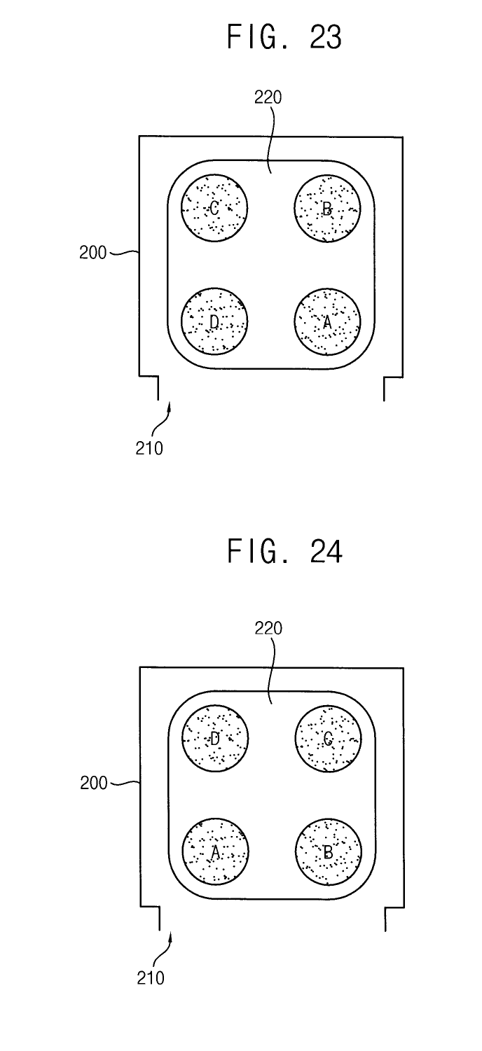

Referring to FIGS. 20 and 23, in step S30, the loading plate 220 may be rotated by about 90° (e.g., ¼ rotation of the loading plate 220) so that the first station may be changed into a second station. A first deposition of a second passivation layer may occur in the second station.

As described above, the second passivation layer may be formed in conditions of a high power, a low pressure and a low flow rate. Thus, the second passivation layer may have an excellent compressive property. For example, the second passivation layer may be formed to have a thickness of about 1,800 Å by the first deposition.

Referring to FIGS. 20 and 24, in step S40, the loading plate 220 may be further rotated by about 900 (e.g., ¼ rotation of the loading plate 220) so that the second station may be changed in to a third station. A second deposition of the second passivation layer may occur in the third station. For example, the second passivation layer may have an additional thickness of about 1,800 Å by the second deposition.

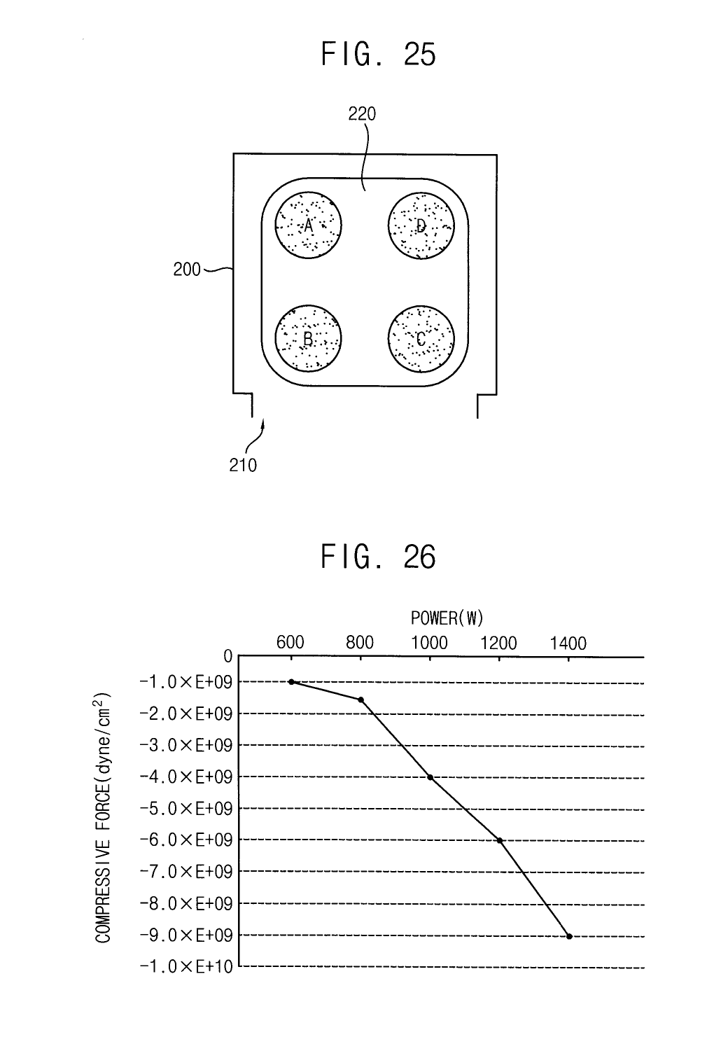

Referring to FIGS. 20 and 25, in step S50, the loading plate 220 may be further rotated by about 900 (e.g., ¼ rotation of the loading plate 220) so that the third station may be changed in to a fourth station. A third deposition of the second passivation layer may occur in the fourth station. For example, the second passivation layer may have an additional thickness of about 1,800 Å by the third deposition.

Accordingly, the second passivation layer having a total thickness of about 5,400 Å may be formed on the first passivation layer. After completing the formation of the second passivation layer, the wafers may be unloaded from the process chamber 200 in step of S60. For example, the second wafer B and the third wafer C may be unloaded from the process chamber 200 through the inlet 210. The loading plate 220 may be rotated by about 180° (e.g., ½ rotation of the loading plate 220), and then the first wafer A and the fourth wafer D may be unloaded from the process chamber 200.

In example embodiments, the first passivation layer having a relatively small thickness may be deposited simultaneously on all wafers in a single station. The second passivation layer having a relatively large thickness may be formed by repeating a plurality of stations, e.g., by 3 stations. Therefore, the second passivation layer having a uniform thickness may be formed on all the wafers loaded in the process chamber 200. Further, each deposition may occur simultaneously on all the wafers throughout all the stations so that the deposition process may be simplified.

FIGS. 20 to 25 illustrate that 4 wafers are loaded in the process chamber 200. However, the number of the wafers loaded in the process chamber 200 is not specifically limited.

For example, in a case that n wafers are loaded in the process chamber, the deposition process may be performed through stations of n times. In this case, the first passivation layer may be deposited by a first station, and each station may be defined by 1/(n−1) rotation of the loading plate. The second passivation layer may be deposited through the stations of (n−1) times, and 1/(n−1) of a total thickness of the second passivation layer may be deposited by each of the stations. For example, n is a positive integer ranging from 3 to 8.

Hereinafter, properties of the passivation layer in accordance with example embodiments are described with reference to Experimental Examples.

### Experimental Example 1

### Evaluation of Compressive Properties of Passivation Layers

A compressive force for correcting a U-shaped warpage that occurs after a back-lapping process based on a silicon wafer of 40 μm was measured, and a target compressive force was determined. A minimum compressive force for correcting the warpage was measured as 6.0×10⁹ dyne/cm² (represented by an absolute value). The target compressive force was set as 8.0×10⁹ dyne/cm².

Passivation layers including silicon nitride were formed on the silicon wafers varying process conditions by a PECVD process in which SiH₄ and NH₃ are used as reaction gases.

Compressive forces of the passivation layers were measured varying powers applied to a process chamber. The compressive forces of the passivation layers were also measured varying pressures applied to the process chamber. A thickness of each passivation layer was set as 5,000 Å.

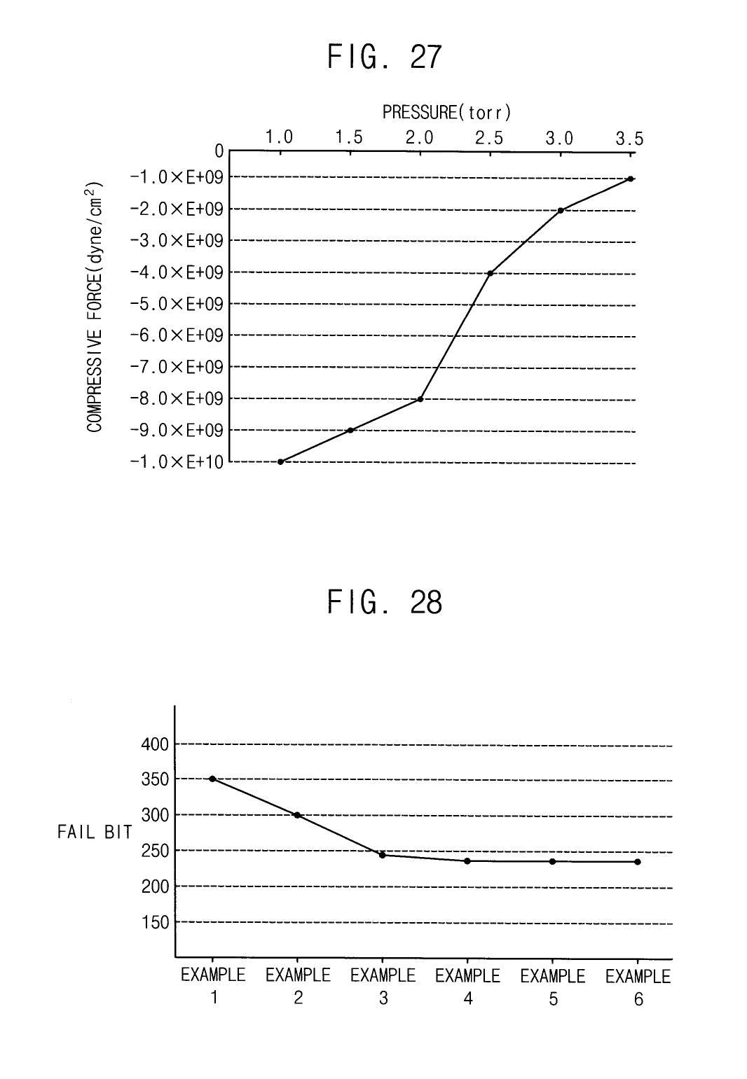

FIGS. 26 to 27 are graphs showing compressive forces of a passivation layer measured in relation to powers and pressures applied to a process chamber.

Referring to FIG. 26, as the power applied to the process chamber became increased, an absolute value of the compressive force of the passivation layer was increased.

In an example embodiment, the passivation layer had the compressive force less than about 4.0×10⁹ dyne/cm² at the power of less than about 1,000 W. Particularly, the compressive force was measured to be less than about 2.0×10⁹ dyne/cm² at the power of less than about 800 W. The compressive force was reached nearly zero at the power of about 400 W.

When the power was increased to a value of about 1,200 W, the compressive force reached to the minimum compressive force for correcting the warpage of about 6.0×10⁹ dyne/cm². The compressive force was reached to the target compressive force of about 8.0×10⁹ dyne/cm² at the power of about 1,300 W. When the power was increased to about 1,400 W, the compressive force was increased to about 9.0×10⁹ dyne/cm².

Referring to FIG. 27, as the pressure applied to the process chamber was increased, the absolute value of the compressive force of the passivation layer was decreased.

Specifically, the minimum compressive force of about 6.0×10⁹ dyne/cm² was obtained at the pressure of about 2.2 torr, and the target compressive force of about 8.0>10⁹ dyne/cm² was obtained at the pressure of about 2 torr. When the pressure was decreased to about 1.5 torr, the compressive force of about 9.0×10⁹ dyne/cm² was achieved. When the pressure was increased to about 3 torr, the compressive force was decreased to about 2.0×10⁹ dyne/cm². The compressive force was measured to be nearly zero at the pressure of about 4 torr.

As shown in FIGS. 26 and 27, the second passivation layer may be formed at a pressure ranging from about 1,200 W to about 1,400 W and/or at a pressure ranging from about 1.5 torr to about 2.2 torr to possess a sufficient compressive force. The first passivation layer may be formed at a pressure ranging from about 400 W to about 800 W and/or at a pressure ranging from about 3 torr to about 4 torr to possess a relatively low compressive force and an enhanced refresh property.

The power and the pressure of the process chamber were set as 1,200 W and 2 torr, respectively, and the compressive forces were measured varying a thickness of the passivation layer including silicon nitride. The result showed that the thickness and the compressive force of the passivation layer were in a nearly proportional relationship. The minimum compressive force of about 6.0>10⁹ dyne/cm² was obtained at the thickness of about 4,000 Å, and the target compressive force of about 8.0×10⁹ dyne/cm² was obtained at the thickness of about 5,000 Å. The compressive force of about 9.0×10⁹ dyne/cm² was achieved at the thickness of about 6,000 Å.

### Experimental Example 2

### Evaluation of Refresh Properties at Various Thicknesses of Passivation Layers

A first passivation layer was formed on the silicon wafer at a power of 800 W and at a pressure of 3 torr. A second passivation layer was formed on the first passivation layer at a power of 1,400 W and at a pressure of 2 torr to have a thickness of about 5,500 Å. Thus, a double-layered passivation layer structure was obtained. The thickness of the first passivation layer was adjusted in each Example as shown in Table 1 below.

TABLE 1

| | Exam- | Exam- | Exam- | Exam- | Exam- | Exam- |
|---|---|---|---|---|---|---|
| | ple 1 | ple 2 | ple 3 | ple 4 | ple 5 | ple 6 |
| Thickness | 300 | 400 | 500 | 600 | 800 | 1,000 |
| of the first | | | | | | |
| passivation | | | | | | |
| layer (Å) | | | | | | |

The double-layered passivation layer structure was implemented to a DRAM device to evaluate the refresh property thereof. Specifically, the number of fail bits per hour was measured in the DRAM device in each Example. The number of the fail bits represents the number of cells failing to preserve charges in a capacitor of the DRAM device.

A single-layered passivation layer of Comparative Example was formed using silicon nitride at a power of 2.8 torr and at a power of 850 W to have a thickness of 6,000 Å. The number of the fail bits measured using the passivation layer of Comparative Example was 354.

FIG. 28 is a graph showing the number of fail bits measured with passivation layers of Examples.

Referring to FIG. 28, as the thickness of the first passivation layer became increased, the number of the fail bits was decreased as shown in Examples 1 to 3. Particularly, when the thickness of the first passivation layer reached about 400 Å (Example 2), the number of the fail bits was below about 300.

However, when the thickness of the first passivation layer was above about 500 Å, the number of the fail bits was slightly and gradually decreased. When the thickness of the first passivation layer was above about 600 Å, the number of the fail bits was maintained at a substantially constant level.

Accordingly, a target thickness of the first passivation layer may be set to, e.g., about 500 Å and the second passivation layer may be formed on the first passivation layer, so that a refresh property of a DRAM device may be improved while obtaining a proper compressive force for correcting a warpage.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
a structure including a transistor and a capacitor on a substrate;
an upper insulation layer covering the structure;
a first passivation layer formed on the upper insulation layer; and
a second passivation layer formed on the first passivation layer and having a compressive property.

2. The semiconductor device of claim 1, wherein the first passivation layer and the second passivation layer include silicon nitride, and
wherein a layer property of the first passivation layer is different from that of the second passivation layer.

3. The semiconductor device of claim 2, wherein the second passivation layer has a layer density greater than that of the first passivation layer.

4. The semiconductor device of claim 2, wherein the first passivation layer has a hydrogen content greater than that of the second passivation layer.

5. The semiconductor device of claim 2, wherein the first passivation layer has a compressive force less than about 2.0>10⁹ dyne/cm², and the second passivation layer has a compressive force ranging from about 6.0×10⁹ dyne/cm² to about 9.0×10⁹ dyne/cm².

6. The semiconductor device of claim 1, wherein the first passivation layer has a thickness ranging from about 400 Å to about 600 Å.

7. The semiconductor device of claim 1, wherein the second passivation layer has a thickness ranging from about 4,000 Å to about 6,000 Å.

8. A method of manufacturing a semiconductor device, comprising:
forming a transistor and a capacitor on a semiconductor wafer;
forming an upper insulation layer which covers the transistor and the capacitor;
forming a first passivation layer on the upper insulation layer, the first passivation layer being formed by a plasma enhanced chemical vapor deposition (PECVD) process; and
forming a second passivation layer which has a compressive property on the first passivation layer by a PECVD process.

9. The method of claim 8, wherein the second passivation layer is formed with a higher power, a lower flow rate of a reaction gas and a lower pressure than used in a formation of the first passivation layer.

10. The method of claim 9, wherein the first passivation layer is formed with a power ranging from about 400 W to about 800 W, and the second passivation layer is formed with a power of about 1,200 W to about 1,400 W.

11. The method of claim 9, wherein the first passivation layer is formed with a pressure ranging from about 3 torr to about 4 torr, and the second passivation layer is formed with a pressure of about 1.5 torr to about 2.2 torr.

12. The method of claim 8, wherein the first passivation layer and the second passivation layer are formed in a same process chamber in-situ.

13. The method of claim 12, wherein the PECVD process is performed using silane and ammonia as a reaction gas.

14. The method of claim 12, wherein the forming the first passivation layer and the forming the second passivation layer include:
loading n number of semiconductor wafers, each of which includes the transistor, the capacitor and the upper insulation layer formed thereon on a loading plate of the process chamber;
forming the first passivation layer on each of the semiconductor wafers;
forming the second passivation layer through stations of (n−1) times, each of the stations being defined by 1/(n−1) rotation of the loading plate; and
unloading the semiconductor wafers including the first passivation layer and the second passivation layer formed thereon,
wherein n is a positive integer ranging from 3 to 8.

15. The method of claim 14, wherein n is 4, the first passivation layer is formed through a single station, and the second passivation layer is formed through the stations of 3 times, and
wherein the first passivation layer has a thickness ranging from about 400 Å to about 2,000 Å, and the second passivation layer has a thickness ranging from about 4,000 Å to about 6,000 Å.

16. The method of claim 15, wherein the first passivation layer has a thickness ranging from about 400 Å to about 600 Å.

17. A method of manufacturing a semiconductor device, comprising:
loading a plurality of wafers having transistors and capacitors thereon in a process chamber;
depositing a first silicon nitride layer over the transistors and capacitors;
rotating plates loaded with the plurality of wafers;
performing a first deposition of a second nitride layer over the first nitride layer;
rotating the plates loaded with the plurality of wafers;
performing a second deposition of the second nitride layer over the second nitride layer; and
unloading the plurality of wafers.

18. The method of claim 17, wherein the first silicon nitride layer has a refresh property greater than that of the second nitride layer.

19. The method of claim 17, wherein the first silicon nitride layer has a thickness less than that of the second nitride layer.

20. The method of claim 19, wherein the method is performed in a PECVD chamber.
